(19) United States
(12) Patent Application Publication
(10) Pub. No.: US 2020/0178398 A1
(43) Pub. Date: Jun. 4, 2020

(54) WIRING BOARD

(71) Applicants: KABUSHIKI KAISHA TOSHIBA, Minato-ku (JP); TOSHIBA ELECTRONIC DEVICES & STORAGE CORPORATION, Minato-ku (JP)

(72) Inventors: Kota TOKUDA, Kawasaki (JP); Kiyokazu ISHIZAKI, Inagi (JP); Nobuhiro YAMAMOTO, Yokohama (JP)

(73) Assignees: KABUSHIKI KAISHA TOSHIBA, Minato-ku (JP); TOSHIBA ELECTRONIC DEVICES & STORAGE CORPORATION, Minato-ku (JP)

(21) Appl. No.: 16/567,652

(22) Filed: Sep. 11, 2019

(30) Foreign Application Priority Data
Dec. 3, 2018 (JP) 2018-226617

(51) Int. Cl. H05K 3/42; H05K 3/10; B32B 15/092; B32B 15/20; H05K 1/05; H05K 1/02

(52) U.S. Cl. CPC H05K 3/428; H05K 3/107; B32B 15/092; H05K 2201/10189; H05K 1/05; H05K 1/0201; H05K 3/422; B32B 15/20

(57) ABSTRACT

According to one embodiment, a wiring board is disclosed. The wiring board includes a first insulating layer, a first conductive pattern, and a first conductive layer. The first conductive pattern is provided in the first insulating layer. The first conductive layer faces part of the first conductive pattern via the first insulating layer and is in an electrically floating state.

### CROSS-REFERENCE TO RELATED APPLICATIONS

This application is based upon and claims the benefit of priority from Japanese Patent Application No. 2018-226617, filed Dec. 3, 2018, the entire contents of which are incorporated herein by reference.

### FIELD

Embodiments described herein relate generally to a wiring board.

### BACKGROUND

When wiring boards such as printed wiring boards and circuit boards are used in harsh environments (for example, in hot and humid environments), metal dendritically grows between electrodes in the wiring board (ion migration), which may result in an insulation failure of short-circuiting between the electrodes.

### BRIEF DESCRIPTION OF THE DRAWINGS

FIG. 1 is a plan view showing a wiring board according to a first embodiment.

FIG. 2 is a sectional view taken along the line 2-2 of FIG. 1.

FIG. 3 is a sectional view showing a wiring board of a comparative example.

FIG. 4 is a sectional view for explaining an example of a manufacturing method of the wiring board according to the first embodiment.

FIG. 5 is a sectional view subsequent to FIG. 4 for explaining the example of the manufacturing method of the wiring board according to the first embodiment.

FIG. 6 is a sectional view subsequent to FIG. 5 for explaining the example of the manufacturing method of the wiring board according to the first embodiment.

FIG. 7 is a sectional view subsequent to FIG. 6 for explaining the example of the manufacturing method of the wiring board according to the first embodiment.

FIG. 8 is a sectional view subsequent to FIG. 7 for explaining the example of the manufacturing method of the wiring board according to the first embodiment.

FIG. 9 is a sectional view subsequent to FIG. 8 for explaining the example of the manufacturing method of the wiring board according to the first embodiment.

FIG. 10 is a plan view showing the wiring board according to a modified example of the first embodiment.

FIG. 11 is a sectional view taken along the line 11-11 of FIG. 10.

FIG. 12 is a plan view showing a wiring board according to a second embodiment.

FIG. 13 is a sectional view taken along the line 13-13 of FIG. 12.

FIG. 14 is a sectional view for explaining an example of a manufacturing method of the wiring board according to the second embodiment.

FIG. 15 is a sectional view showing the wiring board according to a modified example of the second embodiment.

FIG. 16 is a sectional view showing a wiring board according to a third embodiment.

FIG. 17 is a sectional view showing details enclosed in broken lines of FIG. 16.

FIG. 18 is a sectional view showing the wiring board according to a modified example of the third embodiment.

### DETAILED DESCRIPTION

In general, according to one embodiment, a wiring board is disclosed. The wiring board includes a first insulating layer, a first conductive pattern, and a first conductive layer. The first conductive pattern is provided in the first insulating layer. The first conductive layer faces part of the first conductive pattern via the first insulating layer and is in an electrically floating state.

Embodiments will be described hereinafter with reference to the accompanying drawings. The drawings are schematic or conceptual drawings, and dimensions and ratios are not necessarily the same as those in reality. Further, in the drawings, the same reference symbols (including those having different subscripts) denote the same or corresponding parts, and overlapping explanations thereof will be made as necessary. In addition, as used in the description and the appended claims, what is expressed by a singular form shall include the meaning of “more than one”.

### First Embodiment

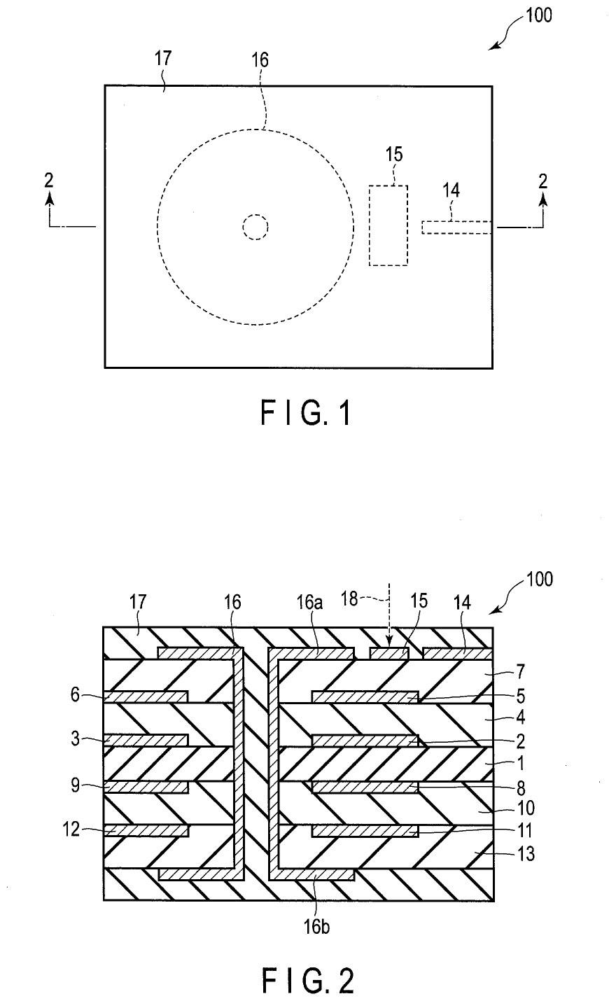

FIG. 1 is a plan view showing a wiring board 100 according to a first embodiment. FIG. 2 is a sectional view taken along the line 2-2 of FIG. 1.

The wiring board 100 is, for example, a printed wiring board or a printed circuit board. The printed wiring board is a board including printed wiring. The printed wiring includes a conductive pattern for connecting components. The printed wiring board is a rigid printed wiring board in which an inflexible insulating base material is used, a flexible printed wiring board in which a flexible base material is used, or the like. The printed circuit board is a board including a printed circuit. The printed circuit is a circuit including printed wiring and components (for example, a resistor, a capacitor, and a transistor) mounted thereon. The wiring board 100 is used in, for example, a hard disk drive.

The wiring board 100 includes an insulating layer 1, a conductive pattern 2, a conductive pattern 3, an insulating layer 4, a conductive pattern 5, a conductive pattern 6, an insulating layer 7, a conductive pattern 8, a conductive pattern 9, an insulating layer 10, a conductive pattern 11, a conductive pattern 12, an insulating layer 13, a conductive pattern 14, a conductive layer 15, a plating member 16, and a solder resist 17.

The conductive patterns 2 and 3 and the insulating layer 4 covering the conductive patterns 2 and 3 are provided on the front surface side of the insulating layer (insulating base material) 1. The conductive patterns 5 and 6 and the insulating layer 7 covering the conductive patterns 5 and 6 are provided on the insulating layer 4. Similarly, the conductive patterns 8 and 9, the insulating layer 10, the conductive patterns 11 and 12, and the insulating layer 13 are provided on the back surface side of the insulating layer 1.

In FIG. 2, for the sake of simplification, the insulating layers 4 and 7 are drawn in distinguishable manner. However, for example, when the insulating layers 4 and 7 are made of the same material, the insulating layers 4 and 7 (first insulating layer) are not necessarily distinguishable. The same is true of the insulating layers 10 and 13.

The conductive pattern 14 and the conductive layer 15 are provided on the insulating layer 7. The conductive layer 15 is disposed separately from the conductive pattern 14, and the conductive layer 15 faces part of the conductive pattern 5 via the insulating layer 7. The conductive layer 15 is provided to suppress moisture absorption by the insulating layer 4 and the insulating layer 7. The potential of the conductive layer 15 is in a floating state unlike that of a wiring pattern electrically connecting components. That is, the conductive layer 15 is electrically isolated from the conductive patterns 2, 3, 5, 6, 8, 9, 11, and 12. A material of the conductive layer 15 is, for example, copper. An experiment conducted by the present inventors has confirmed that copper has a great effect in suppressing moisture absorption.

The plating member 16 penetrates the insulating layers 1, 4, 7, 10, and 13. In the process of forming the plating member 16, the plating member 16 is formed to cover a side surface of a through-hole opened in the insulating layers 1, 4, 7, 10, and 13. The plating member 16 includes a portion 16a extending on the insulating layer 7 and a portion 16b extending on the insulating layer 13. The portion 16a faces part of the conductive patterns 5 and 6, and the portion 16b faces part of the conductive patterns 11 and 12.

The solder resist 17 is provided to cover the insulating layer 7, the insulating layer 13, the conductive pattern 14, the conductive layer 15, and the plating member 16, and to close the through-hole.

In the present embodiment, the insulating layers 1, 4, 7, 10, and 13 include epoxy resin. The epoxy resin is apt to absorb moisture (water vapor). Thus, when the wiring board 100 is used in a hot and humid environment, for example, in an emerging nation, the insulating layers 1, 4, 7, 10, and 13 are apt to absorb moisture.

However, according to the present embodiment, even in a hot and humid environment, the entrance of moisture (water vapor) 18 in the atmosphere into the insulating layers 7 and 4 can be suppressed by the conductive layer (moisture absorption suppressing member) 15 as shown in FIG. 2. It is therefore possible to suppress, for example, the occurrence of an insulation failure between the conductive pattern 2 and the plating member 16, which are adjacent in a transverse direction, and an insulation failure between the conductive pattern 5 and the plating member 16, which are adjacent in a transverse direction, due to ion migration.

The plating member 16 is a conductive pattern through which an especially large current flows. Thus, in order to effectively suppress ion migration between the plating member 16 and the conductive pattern 5 adjacent thereto, it is preferable that the conductive layer 15 be provided at a position close to both the conductive pattern 5 and the plating member 16.

Note that, a conductive layer (moisture absorption suppressing portion) may also be provided on the insulating layer 13 side (back surface side). In this case, the occurrence of an insulation failure between the conductive pattern 8 and the plating member 16, which are adjacent in a transverse direction, and an insulation failure between the conductive pattern 11 and the plating member 16, which are adjacent in a transverse direction, also can be suppressed.

In future, when there is further progress in measures for insulation against an increase in a current flowing through the conductive patterns (wiring) of the wiring board 100, in the degree of integration of components, and in an increase in density, a gap between the conductive patterns (wiring) in the wiring board 100 will become narrower. Thus, it will be more and more important to be able to suppress the occurrence of an insulation failure as in the present embodiment. For example, the gap in wiring is less than or equal to 75 μm.

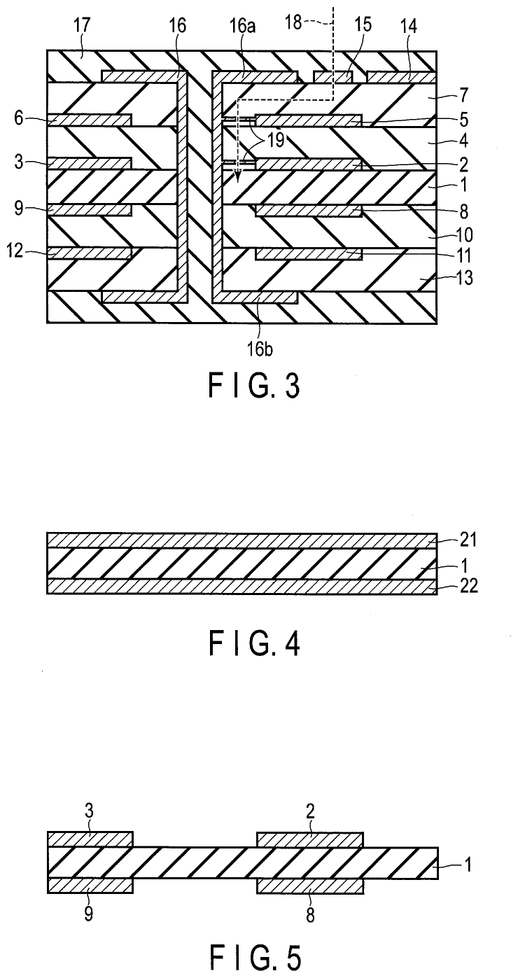

In contrast, in the case of a wiring board (comparative example) which does not include the conductive layer (moisture absorption suppressing member) 15, the moisture (water vapor) 18 easily enters the insulating layers 7 and 4 as shown in FIG. 3, and metal 19 precipitates so as to electrically connect the conductive pattern 2 and the plating member 16, so that an insulation failure is likely to occur between the conductive pattern 2 and the plating member 16. Similarly, an insulation failure is likely to occur also between the conductive pattern 5 and the plating member 16.

Note that, in general, an insulation failure between conductive patterns adjacent in a transverse direction due to ion migration is more apt to occur than an insulation failure between conductive patterns adjacent in a longitudinal direction (for example, between the conductive pattern 2 and the conductive pattern 5) due to ion migration. It is therefore preferable that a conductive layer which suppresses moisture absorption be provided to cover an insulating layer directly above a space between two conductive patterns (for example, wiring patterns) arranged side by side in a transverse direction.

In addition, the conductive layer 15 also suppresses the entrance of contaminants in the atmosphere into the insulating layer 7 and the insulating layer 4. Conductive contaminants may cause an insulation failure. In this manner, the conductive layer 15 also suppresses the occurrence of an insulation failure caused by a factor other than moisture (water vapor).

FIG. 4 to FIG. 9 are sectional views for explaining an example of a manufacturing method of the wiring board 100.

First, as shown in FIG. 4, a member (core board) constituted of the insulating layer 1, a conductive layer 21 covering the front surface of the insulating layer 1 and a conductive layer 22 covering the back surface of the insulating layer 1 is prepared. Here, the insulating layer 1 is an epoxy resin layer, and the conductive layer 21 and the conductive layer 22 are copper foil.

Next, the conductive layer 21 and the conductive layer 22 are processed by using a photolithographic process and an etching process, and as shown in FIG. 5, the conductive patterns 3 and 2 are formed on the front surface of the insulating layer 1, and the conductive patterns 9 and 8 are formed on the back surface of the insulating layer 1.

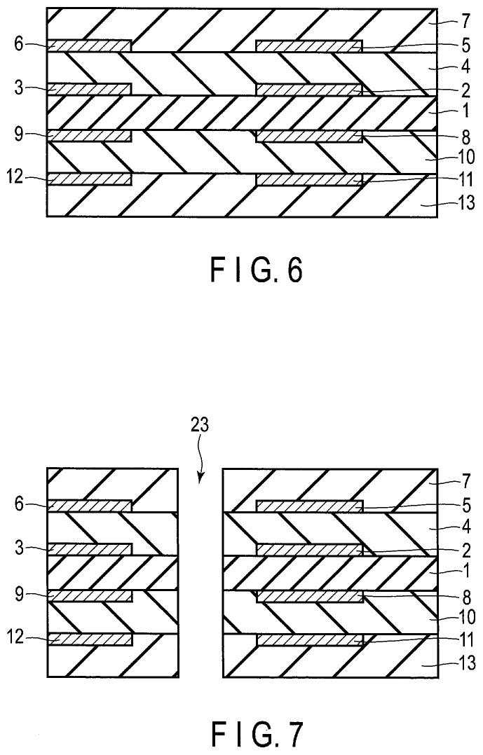

Next, as shown in FIG. 6, the insulating layer 4 covering the conductive patterns 2 and 3 is formed on the front surface side of the insulating layer 1, and the insulating layer 10 covering the conductive patterns 8 and 9 is formed on the back surface side of the insulating layer 1. The insulating layers 4 and 10 include, for example, a prepreg. The prepreg includes a glass woven fabric and epoxy resin with which the glass woven fabric is impregnated. A glass nonwoven fabric may be used instead of the glass woven fabric.

Then, similarly, the conductive patterns 5 and 6 and the insulating layer 7 are sequentially formed on the insulating layer 4, and the conductive patterns 11 and 12 and the insulating layer 13 are sequentially formed under the insulating layer 10.

Next, as shown in FIG. 7, a through-hole 23 penetrating the insulating layers 7, 4, 1, 10, and 13 is formed. The through-hole 23 does not penetrate the conductive patterns 2, 3, 5, 6, 8, 9, 11, and 12. The through-hole 23 is formed, for example, by using a laser.

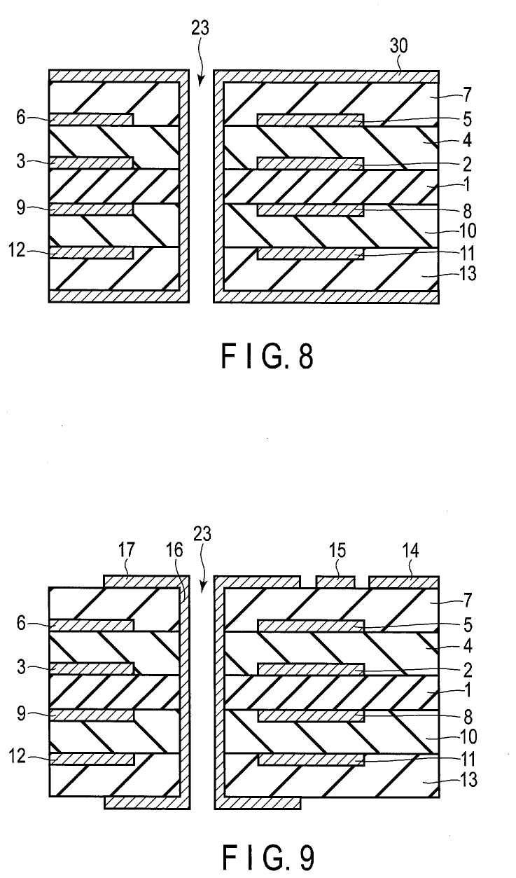

Next, as shown in FIG. 8, a plating layer 30 covering the inner surface (side surface) of the through-hole 23, the front surface of the insulating layer 7, and the back surface of the insulating layer 13 is formed. Here, the plating layer 30 includes copper, and is formed, for example, by using electroless plating.

Next, the plating layer 30 is processed by using a photolithographic process and an etching process, and the conductive pattern 14, the conductive layer 15, and the plating member 16 are formed as shown in FIG. 9. When the manufacturing method according to the present embodiment is employed, the conductive pattern 14, the conductive layer 15, and the plating member 16 include the same material (copper), but do not necessarily include the same material.

Then, a solder resist (not shown) covering the conductive pattern 14, the conductive layer 15, and the plating member 16 is formed to fill the through-hole 23, and the wiring board 100 shown in FIG. 1 is thereby obtained.

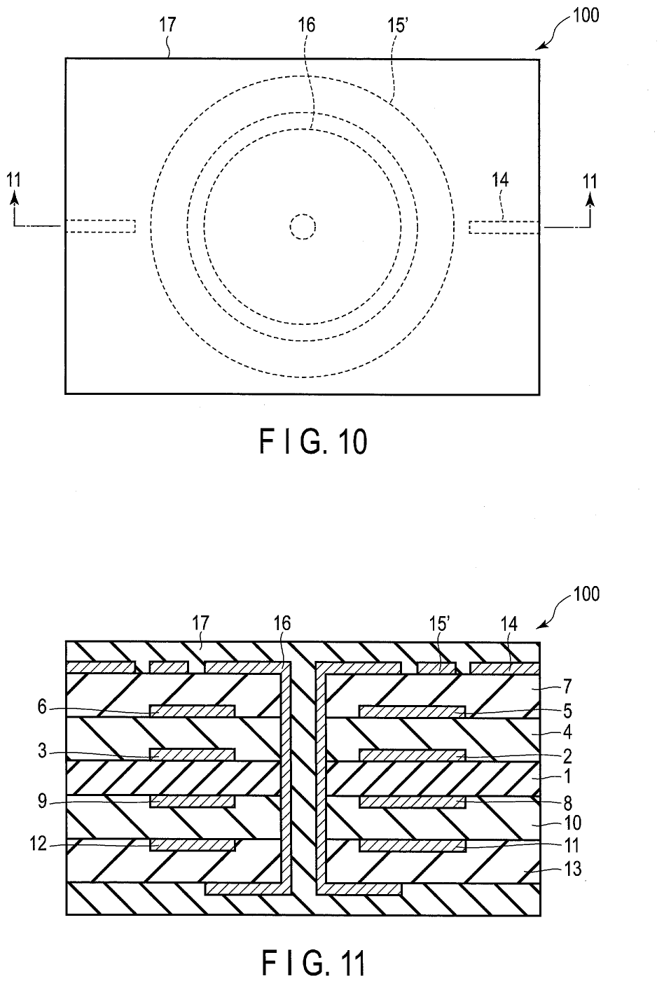

FIG. 10 is a plan view showing the wiring board 100 according to a modified example of the present embodiment, and FIG. 11 is a sectional view taken along the line 11-11 of FIG. 10.

In the wiring board 100 according to the present modified example, an annular conductive layer 15′ is adopted. It is therefore possible to suppress an insulation failure between the conductive pattern 3 and the plating member 16 and an insulation failure between the conductive pattern 6 and the plating member 16. Moreover, the conductive layer 1, which is annular, may also be provided on the insulating layer 13 side. In this case, it is also possible to suppress an insulation failure between the conductive pattern 8 and the plating member 16, an insulation failure between the conductive pattern 9 and the plating member 16, an insulation failure between the conductive pattern 11 and the plating member 16, an insulation failure between the conductive pattern 12 and the plating member 16.

### Second Embodiment

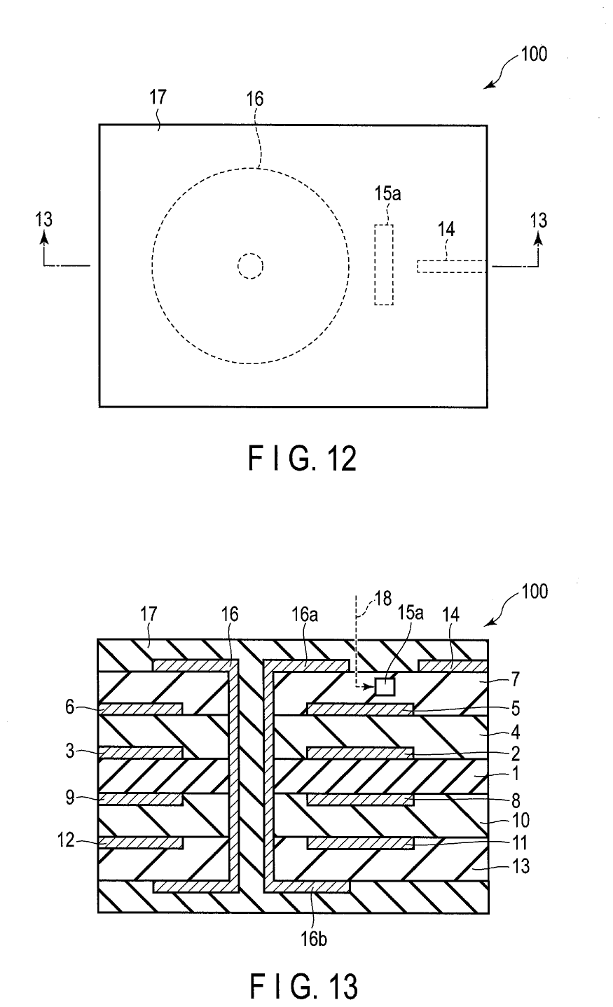

FIG. 12 is a plan view showing a wiring board 100 according to a second embodiment. FIG. 13 is a sectional view taken along the line 13-13 of FIG. 12.

The present embodiment differs from the first embodiment in that a desiccant 15a is used instead of a conductive layer (moisture absorption suppressing member) 15. In the present embodiment, the desiccant 15a is embedded in an insulating layer 7. Raw materials of the desiccant 15a include, for example, silica gel, calcium oxide, or calcium chloride. The above raw materials may be provided in a container through which moisture passes.

According to the present embodiment, moisture 18 entering the insulating layer 7 and an insulating layer 4 is absorbed by the desiccant 15a, and thus, for example, the occurrence of an insulation failure between a conductive pattern 2 and a plating member 16 and an insulation failure between a conductive pattern 5 and the plating member 16 can be suppressed.

Note that, the desiccant 15a may also be provided on an insulating layer 13 side. In this case, the occurrence of an insulation failure between a conductive pattern 8 and the plating member 16 and an insulation failure between a conductive pattern 11 and the plating member 16 also can be suppressed. Moreover, the desiccant 15a may also be provided on a conductive pattern 6 side or a conductive pattern 12 side.

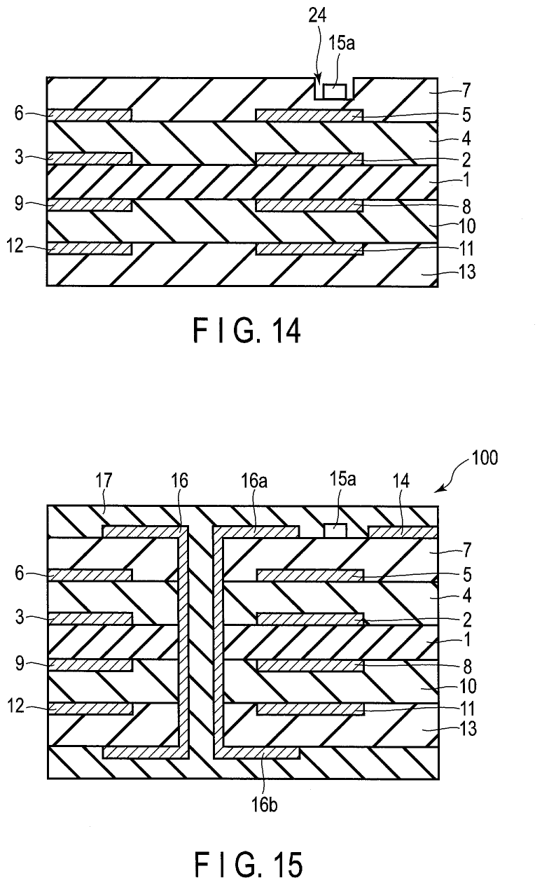

FIG. 14 is a sectional view for explaining an example of a manufacturing method of the wiring board 100 according to the present embodiment.

First, the above-described steps of FIG. 4 to FIG. 6 are carried out. Next, the insulating layer 7 is processed by using a photolithographic process and an etching process, and as shown in FIG. 14, a recess 24 is formed in the front surface of the insulating layer 7 and the desiccant 15a is disposed in the recess 24. Then, the insulating layer 7 is formed again to fill the recess 24, and the wiring board 100 shown in FIG. 13 is thereby obtained.

FIG. 15 is a sectional view showing the wiring board 100 according to a modified example of the present embodiment. In the wiring board 100 according to the present modified example, no recess is provided in the front surface (top surface) of the insulating layer 7, and the desiccant 15a is placed on the front surface (top surface). Note that, a desiccant may also be provided on the insulating layer 13 side.

### Third Embodiment

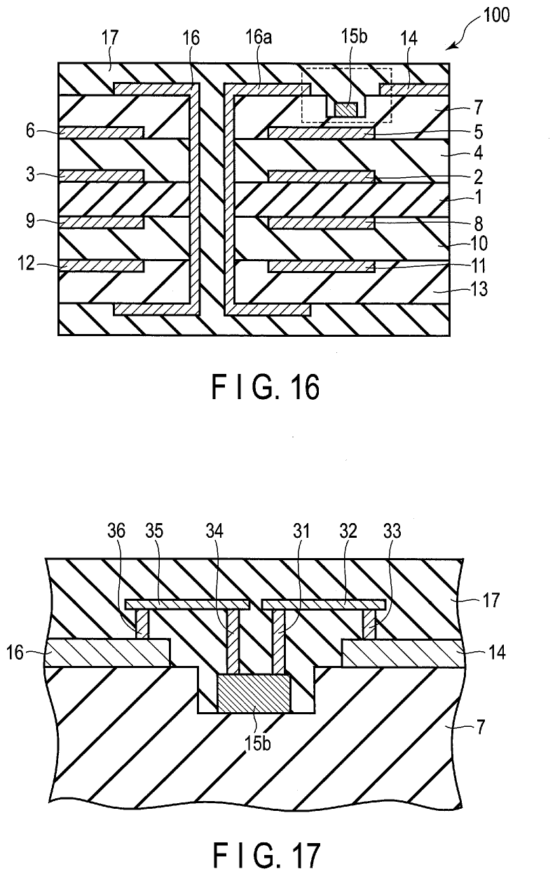

FIG. 16 is a sectional view showing a wiring board 100 according to a third embodiment.

The present embodiment differs from the first embodiment in that a resistor (heat generating member) 15b is used instead of a conductive layer (moisture absorption suppressing member) 15. The resistor 15b is placed in a recess provided in the front surface of an insulating layer 7.

FIG. 17 is a sectional view showing details enclosed in broken lines of FIG. 16 in a case where the potential of a conductive pattern 14 is different from that of a plating member 16. One end of the resistor 15b is electrically connected to the conductive pattern 14 via a plug 31, a wire 32, and a plug 33. The other end of the resistor 15b is electrically connected to the plating member 16 via a plug 34, a wire 35, and a plug 36. Thus, a current can be passed through the resistor 15b, and the resistor 15b can generate heat.

According to the present embodiment, while an insulating layer 4 and the insulating layer 7 are being heated by the resistor 15b, it is hard for moisture in the atmosphere to enter the insulating layers 4 and 7. Thus, for example, the occurrence of an insulation failure between a conductive pattern 2 and the plating member 16 and an insulation failure between a conductive pattern 5 and the plating member 16 can be suppressed. Note that, the resistor 15b may also be provided on an insulating layer 13 side. Moreover, the resistor 15b may also be provided on a conductive pattern 6 side or a conductive pattern 12 side.

Note that, while the wiring board 100 is not operating, the wiring board 100 does not generate heat, so that the moisture may enter the insulating layers 4 and 7 and an insulation failure may occur. The occurrence of such an insulation failure is suppressed by employing a structure configured to generate heat by the resistor 15b even when the wiring board 100 is not operating, which is for example achieved by providing a dedicated wire for supplying a current to the resistor 15b.

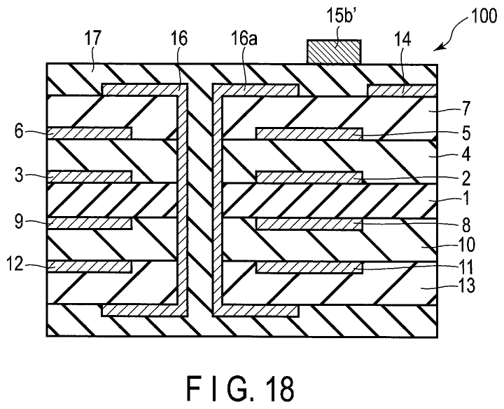

FIG. 18 is a sectional view showing the wiring board 100 according to a modified example of the present embodiment. In the wiring board 100 according to the present modified example, an integrated circuit 15b′ is used as a heat generating member. The integrated circuit 15b′ is placed on an insulating layer in which an insulation failure is likely to occur because of moisture absorption. Because heat is generated while the integrated circuit 15b′ is operating, the occurrence of an insulation failure due to moisture absorption can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wiring board comprising:
a first insulating layer;
a first conductive pattern provided in the first insulating layer; and
a first conductive layer facing part of the first conductive pattern via the first insulating layer and being in an electrically floating state.

2. The wiring board of claim 1, wherein the first conductive layer is provided on the first insulating layer.

3. The wiring board of claim 2, further comprising a plating member penetrating the first insulating layer.

4. The wiring board of claim 3, wherein the plating member includes a portion extending on the first insulating layer, and
the portion faces part of the first conductive pattern via the first insulating layer.

5. The wiring board of claim 4, wherein the first conductive layer and the plating member include a same material.

6. The wiring board of claim 5, wherein the material includes copper.

7. The wiring board of claim 1, wherein the first insulating layer includes epoxy resin.

8. The wiring board of claim 7, wherein the first conductive pattern includes copper.

9. The wiring board of claim 1, further comprising a second conductive pattern disposed below the first conductive pattern and provided in the first insulating layer.

10. The wiring board of claim 9, further comprising a second insulating layer provided under the second conductive pattern.

11. The wiring board of claim 10, wherein the second conductive pattern includes copper.

12. A wiring board comprising:
a first insulating layer;
a first conductive pattern provided in the first insulating layer; and
a desiccant facing part of the first conductive pattern via the first insulating layer.

13. The wiring board of claim 12, wherein the desiccant is provided in the first insulating layer or on the first insulating layer.

14. The wiring board of claim 12, further comprising a plating member penetrating the first insulating layer.

15. The wiring board of claim 14, wherein the plating member includes a portion extending on the first insulating layer, and
the portion faces part of the first conductive pattern via the first insulating layer.

16. A wiring board comprising:
a first insulating layer;
a first conductive pattern provided in the first insulating layer; and
a heat generating member facing part of the first conductive pattern via the first insulating layer.

17. The wiring board of claim 16, wherein the heat generating member is provided in a recess in a surface of the first insulating layer.

18. The wiring board of claim 17, wherein the heat generating member includes a resistor.

19. The wiring board of claim 16, further comprising a plating member penetrating the first insulating layer.

20. The wiring board of claim 19, wherein the plating member includes a portion extending on the first insulating layer, and
the portion faces part of the first conductive pattern via the first insulating layer.
